(19) United States
(12) Patent Application Publication
(10) Pub. No.: US 2008/0239672 A1
(43) Pub. Date: Oct. 2, 2008

(54) Cooling of High Power Density Devices Using Electrically Conducting Fluids

(75) Inventors: Uttam Ghoshal, Austin, TX (US); Andrew Carl Miner, Austin, TX (US)

Correspondence Address: ZAGORIN O'BRIEN GRAHAM LLP, 7600B NORTH CAPITAL OF TEXAS HIGHWAY, SUITE 350, AUSTIN, TX, 78731, US

(73) Assignee: NANOCOOLERS, INC., Austin, TX (US)

(21) Appl. No.: 10/597,327

(22) PCT Filed: Jan. 20, 2005
(86) PCT No.: PCT/US05/03100

§ 371 Date: Jun. 12, 2008

(30) Foreign Application Priority Data
Jan. 23, 2004 (US) 10763303

(51) Int. Cl. H05K 7/20

(52) U.S. Cl. 361/701

(57) ABSTRACT

A system to extract heat from a high power density device and dissipate heat at a convenient distance. The system circulates liquid metal in a closed conduit using one or more electromagnetic pumps for carrying away the heat from high power density device and rejecting the heat at a heat sink located at a distance. The system may make use of a thermoelectric generator to power the electromagnetic pumps by utilizing the temperature difference between the inlet and outlet pipes of the heat sink. The system also provides networks of primary and secondary closed conduits having series and parallel arrangements of electromagnetic pumps for dissipating heat from multiple devices at a remotely located heat sink.

### TECHNICAL FIELD

The present invention relates to a system for dissipating beat from a high power density device (HPDD). More specifically, the invention relates to a system that helps in effective dissipation of heat at a distance away from the HPDD.

### BACKGROUND ART

Electronic devices such as central processing units, graphic-processing units, laser diodes etc. can generate significant heat during operation. If the generated heat is not dissipated properly from high power density devices, temperature buildup may occur. The buildup of temperature can adversely affect the performance of these devices. For example, excessive temperature buildup may lead to malfunctioning or breakdown of the devices. So, it is important to remove the generated heat in order to maintain normal operating temperatures of these devices.

The heat generated by HPDD is removed by transferring the heat to ambient atmosphere. Several methods are available to transfer heat from a HPDD to the atmosphere. For example, an electric fan placed near a HPDD can blow hot air away from the device. However, a typical electric fan requires a large amount of space and thus it may not be desirable to place a fan near the HPDD due to space constraints in the vicinity of the HPDD. In case of notebook computers or laptops, there is additional constraint on the positioning of the fans due to the compact size of these devices. For at least the foregoing reasons, it would be desirable to provide heat dissipation (e.g. using a fan) at a location away from the HPDD.

Another way to dissipate heat from a HPDD involves the use of a large surface area heat sink. Essentially, the heat sink is placed in contact with the HPDD to transfer heat away from the HPDD into the heat sink. The transferred heat is then dissipated through the surface area of the heat sink, thereby reducing the amount of temperature buildup in the HPDD. In case a significant amount of heat is generated, a larger-sized heat sink is necessary to adequately dissipate the heat. Also in some cases the heat sink cannot be placed adjacent to HPDD due to form factor restriction. This may be due to non-availability of space near the HPDD or due to other devices/components located nearby that cannot withstand the rise in temperature due to dissipated heat. One way of dealing with the form factor limitation is to place a heat sink at a sufficiently large distance from the HPDD. In this case, heat has to be transferred from HPDD to the heat sink before being dissipated to the atmosphere.

A heat pipe is a device that can effectively transfer heat from one point to another. It typically consists of a sealed metal tubular container whose inner surfaces may also include a capillary wicking material. A heat transfer fluid flows along the wick structure of the heat pipe. FIG. 1 shows a heat pipe 101. It has an inner lining 103 of micron scale wick structures. A HPDD 105 transfers heat to an end 107 of heat pipe 101. Liquid at end 107 absorbs the heat, evaporates and moves to a cold end 109 of the heat pipe. The evaporated vapor comes in contact with cold end 109, condenses and dissipates heat. The condensed liquid moves back to end 107 by gravity or by capillary action of the inner lining 103. The wick like structure of lining 103 provides a capillary driving force to return the condensate to end 107.

A heat pipe is useful in transferring heat away from the HPDD when the form factor and other constraints limit dissipation of heat near the HPDD itself. Further, it has the ability to transport heat against gravity with the help of porous capillaries that form the wick.

Heat pipes exploit liquid-vapor phase change properties. Thus, maximum heat transfer is limited by the vapor-liquid nucleation properties. Interface resistance between the metal surface and the liquid layer also limits the maximum heat flow. Heat pipes do not solve the problems of interface resistances at the hot source end and the cold sink end. Interface resistance between the metal surface and the liquid layer also limits the maximum heat flow. It is also not possible to cool multiple hot sources using a single heat pipe. Often these heat pipes contain CFC fluids that are not environment-friendly. The performance of these heat pipes depend on the orientation of the heat pipe structure with-respect to the gravitational forces, operating temperatures, and the nature of fluids in the loop. The dependence of performance on orientation restricts the flexible positioning of heat pipes.

The above-discussed limitations of heat pipes have made forced fluid cooling an attractive option. The forced fluid cooling is based on circulating water through a HPDD. Water carries away heat from the HPDD and dissipates the heat at a sink placed at a distance. The heat is dissipated at the sink using fluid-fluid heat exchangers such as finned radiators with natural or forced convection. In forced fluid cooling, more than one HPDD can be cooled in a single loop.

However, the use of water in forced fluid cooling has some limitations. The low thermal conductivity of water limits its effectiveness as a heat transfer fluid. So, in this case the only mode of transfer of heat is convection. Transfer of heat by conduction is negligible. Also, water is circulated using mechanically moving pumps that may be unreliable, occupy large volumes, and contribute to vibration or noise.

U.S. Pat. No. 3,654,528 entitled “Cooling Scheme For A High Current Semiconductor Device Employing Electromagnetically-Pumped Liquid Metal For Heat And Current Transfer” describes the use of liquid metal to spread heat uniformly in the heat sink placed in contact with a wafer. However, this patent describes heat dissipation in the proximity of the heat-generating device and does not address to the form factor limitation. Further, the use of electromagnetic (EM) pumps requires an extra power supply that generates heat. Removal of this additional heat adds to the burden.

In light of the above discussion it is clear that methods provided by the prior art do not satisfactorily address the issue of removal of heat at a desirable distance away from a high power density device. Thus there is a need for a flexible method for managing dissipation of heat at a distance away from the high power density device.

### MODES FOR CARRYING OUT THE INVENTION

The present invention is described in terms of various embodiments that include or provide a system for effective removal of heat from a high power density device and dissipating the heat at a distance. In some embodiments in accordance with the present invention, such a system includes a liquid metal chamber mounted on a high power density device. The liquid metal chamber can include a solid-fluid heat exchanger or may allow direct contact of the liquid metal with the high power density device. A conduit circulates liquid metal through the liquid metal chamber. The liquid metal carries away the heat generated by the high power density device and dissipates it at a heat exchanger or heat sink provided at a predefined distance away from the device. This system is highly flexible and can be used in different embodiments depending on form factor and flow routing limitations. The same conduit (carrying the liquid metal) can be used for carrying heat away from multiple devices. In addition, the conduit can traverse a bend in a bendable device configuration. Furthermore, heat pipes may be employed in conjunction with the described liquid metal systems to define a thermal transfer pathway away from a high power density device. Multiple pumps arranged in series or parallel arrangements may also be provided. Two or more loops (of the conduit) can use a common pump or common s liquid metal chamber. A loop can dissipate heat, which is further carried away by another loop, more complex networks of loops can also be formed.

### BRIEF DESCRIPTION OF THE DRAWINGS

The present invention may be better understood, and its numerous objects, features, and advantages made apparent to those skilled in the art by referencing the accompanying drawings. Preferred embodiments of the invention will hereinafter be described in conjunction with the accompanying drawings, which are provided to illustrate and not to limit the invention, wherein like designations denote like elements, and in which:

FIG. 1 shows the design of a heat pipe existing in the prior art;

FIG. 2 shows a system for dissipating heat from a high power density device at a distance in accordance with the preferred embodiment of the invention;

FIG. 3 shows the principle of an electromagnetic pump provided by the abovementioned system for circulating liquid metal;

FIG. 4 shows a system for dissipating heat from a high power density device in a folding microelectronic device using flexible conduits in accordance with another embodiment of the invention;

FIG. 5 shows a system for dissipating heat from a high power density device in a folding microelectronic device using a hinge with an integrated conduit in accordance with another embodiment of the invention;

FIG. 6 shows the structure of the hinge shown in FIG. 5;

FIG. 7 shows a system for dissipating heat from a high power density device that uses a liquid metal system and a heat pipe, in accordance with another embodiment of the invention;

FIG. 8 shows another embodiment of a system for dissipating heat from a high power density device using a liquid metal system and a heat pipe, in accordance with yet another embodiment of the invention.

FIG. 9 shows a system for dissipating heat from a high power density device in which liquid metal comes in direct contact with the high power density device, in accordance with another embodiment of the invention;

FIG. 10 shows the use of thermoelectric generator and thermoelectric cooler in the system shown in FIG. 1 in accordance with an alternate embodiment of the invention;

FIG. 11 shows an alternate embodiment that has a fluid-fluid heat exchanger in combination with the heat sink;

FIG. 12A shows an embodiment that has two electromagnetic pumps in series;

FIG. 12B shows an embodiment that has two electromagnetic pumps placed in parallel; and

FIG. 13 shows a complex network that utilizes a combination of multiple primary and secondary closed conduits for removing heat from multiple high power density devices.

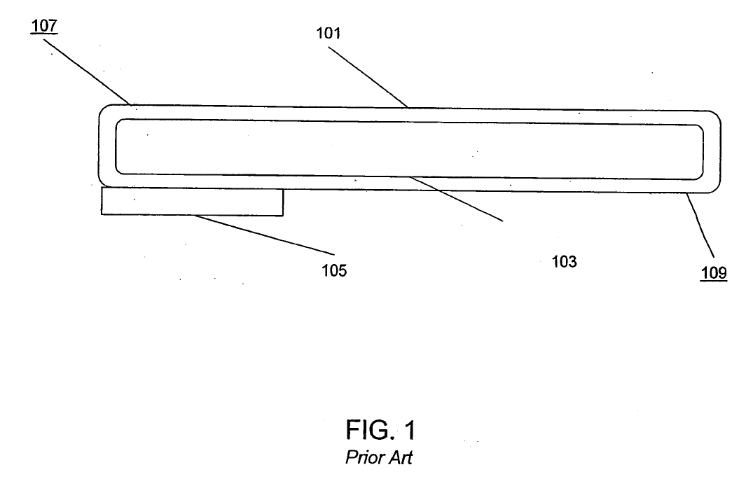

### DISCLOSURE OF THE INVENTION

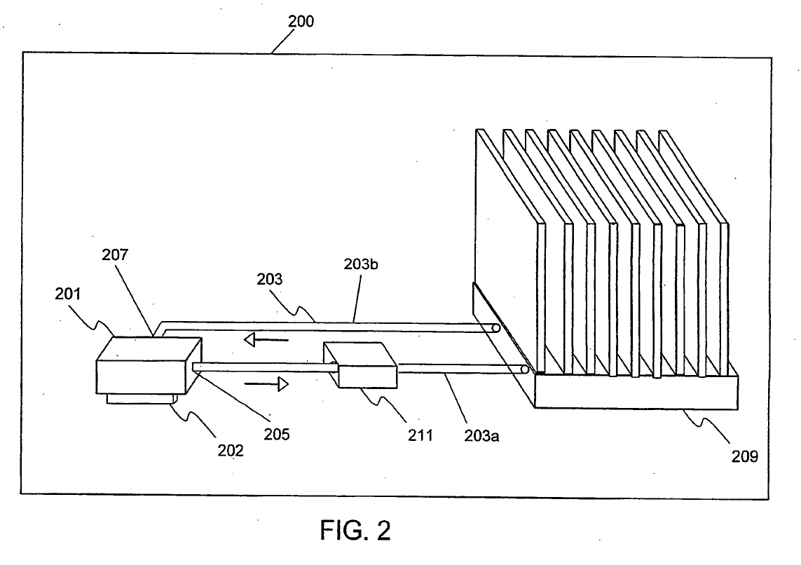

The present invention is described in terms of various embodiments that include or provide a system for effective removal of heat from a high power density device and dissipating the heat at a distance. In some embodiments in accordance with the present invention, such a system includes a liquid metal chamber mounted on a high power density device. The liquid metal chamber can include a solid-fluid heat exchanger or may allow direct contact of the liquid metal with the high power density device. FIG. 2 shows solid-fluid heat exchanger 201 placed adjacent to a high power density device 202. Solid-fluid heat exchanger 201 is filled with liquid metal that absorbs the heat from the high power density device 202. A conduit 203 passes through solid-fluid heat exchanger 201 that takes away the liquid metal through an end 205 of solid-fluid heat exchanger 201 and brings liquid metal back into solid-fluid heat exchanger 201 through an end 207. Section 203a of conduit 203 carries hot liquid metal away from end 205 of solid-fluid heat exchanger 201 to a heat sink 209 provided at a predefined distance from solid-fluid heat exchanger 201. Heat sink 209 releases the heat to the atmosphere. The cooled liquid metal is then circulated back to solid-fluid heat exchanger 201 through section 203b of conduit 203. An electromagnetic pump 211 provides the power for circulating the liquid metal in the form of a closed loop. In this manner, system 200 provides for the transport and dissipation of heat at a predefined distance away from high power density device 202. This distance is determined based on the form factor (the configuration and physical arrangement of the various components in and around the high power density device 202). Thus system 200 provides for heat dissipation in the cases where dissipating heat in the proximity of the high power density device 202 is not desirable. For example, in a computer, in case the heat dissipated by components such as the microprocessor or the power unit is in proximity of components like memory, this heat may lead to permanent loss of data from memory. Thus it is desirable that the heat generated by the microprocessor/power unit is dissipated at a position away from components that may get damaged.

Heat sink 209 is constructed of a low thermal resistance material. Examples of such materials include copper and aluminum Heat sink 209 has a large surface area for effectively dissipating heat to the atmosphere. Heat sink 209 may dissipate heat by natural convection or by forced convection with the use of a fan. A finned structure (as shown in the figures) is sometimes used as a heat sink. In fact, the finned structure may also have liquid metal circulating through its fins. Based on the description herein, it will be apparent to one skilled in the art that other heat sink structures (used for transferring heat to the atmosphere) may be employed in the system without departing from the scope of the invention.

Conduit 203 is constructed of polymer materials such as Teflon or polyurethane. Alternatively, refractory metals such as vanadium or molybdenum may also be used as the material of construction of conduit 203. Polymers like Teflon prove to be good conduit materials as they are inert to most chemicals, provide low resistance to flow of liquids and are resistant to high temperature corrosion. Solid-fluid heat exchanger 201 includes a thermally conducting surface closely attached to the high power density device and a housing containing the liquid metal. For processor chip cooling applications, the thermally conducting surface could be a thin-film tungsten, nickel layer on the backside of the processor or a discrete surface of tungsten, nickel, anodized aluminum or nickel-coated aluminum soldered to the backside of the chip. The housing material could be an inert polymer (Teflon, polyurethane, etc.), glass or thermally conductive material such as tungsten, nickel, nickel-coated aluminum, anodized aluminum, nickel-coated copper etc.

System 200 may be used for dissipating heat from a wide variety of devices. For example high power density device 202 of FIG. 2 may be a micro scale device like a microelectronic chip, an optoelectronic chip, arrays of hot chips, a laser diode, light emitting diodes (LEDs), an array of LEDs etc. High power density device 202 may also be a central processing unit of a computer, graphical processor unit or a light bulb. System 200 also finds application in biological, chemical, or nuclear reactors to dissipate heat generated by these reactors.

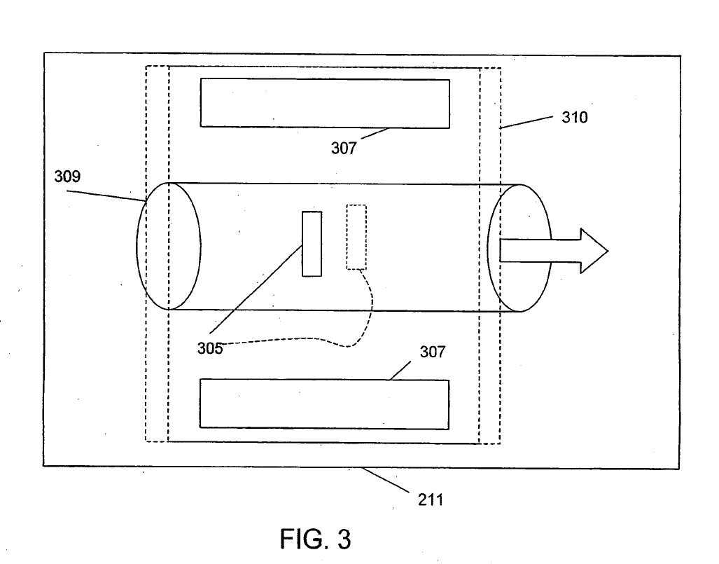

FIG. 3 shows the principle of operation of electromagnetic pumps 211 -employed in the above-mentioned embodiment. Electromagnetic pump 211 includes of a pair of electrode plates 305 placed vertically facing each other. A DC (direct current) voltage is applied across the electrode plates. The DC voltage produces an electric field across electrode plates 305. A pair of permanent magnets 307 is arranged facing each other above and below the plane containing electrode plates 305. A tube 309 carries liquid metal. The direction of magnetic field generated by the permanent magnets 307 is perpendicular to the direction of electric field provided by the electrode plates 305. An electromagnetic force acts on the liquid metal causing it to flow in a direction perpendicular to the plane of electric and magnetic fields (as shown by the block arrow in FIG. 3). Based on the description herein, it will be evident to one skilled in the art that the method of pumping can be implemented in several different ways based on the abovementioned principle. For example, DC electromagnetic pumps (as described above) can be utilized in applications where DC sources are available while induction electromagnetic pumps utilizing polyphase induction coils can be used in cases where physical contact to the liquid metal is undesirable (say, where the liquid metal is corrosive).

In certain applications, the system may need to be provided with electromagnetic interference (EMI) shielding to shield the high power density device from electromagnetic radiations generated by the pump. These electromagnetic radiations, if not shielded, might adversely affect the performance of the high power density device or its components. Accordingly, the electromagnetic pump is enclosed within a housing that shields the high power density device. This EMI shielding may be provided using standard methods such as magnetic shields and ESI shielding tapes. As shown in FIG. 3, magnetic shield 310 confines the magnetic field within the pump. The magnetic shield 310 may be made using high magnetic permeability materials such as steel, nickel, alnico, or permandur or other specially processed materials.

In some embodiments, tube 309 is constructed of polymer materials such as Teflon or polyurethane. Teflon has the advantage that it can be easily machined. Alternatively, refractory metals such as tungsten or molybdenum may also be used as the material of construction of tube 309. Ultra-thin anodized aluminum or nickel-coated aluminum or copper can also be used.

In some embodiments, the liquid metal carried by tube 309 is an alloy of gallium and indium. Preferred compositions comprise 65 to 75% by mass gallium and 20 to 25% indiunl Materials such as tin, copper, zinc and bismuth may also be present in small percentages. One such preferred composition comprises 66% gallium, 20% indium, 11% tin, 1% copper, 1% zinc and 1% bismuth. Some examples of the commercially available Gain alloys include galistan—a concoction popular as a substitute for mercury (Hg) in medical applications, and newmerc. The various properties of Gain alloy make it desirable liquid metal for use in heat spreaders. The GaIn alloy spans a wide range of temperature with high thermal and electrical conductivities. It has melting points ranging from −15° C. to 30° C. and does not form vapor at least up to 2000° C. It is not toxic and is relatively cheap. It easily forms alloys with aluminum and copper. It is inert to polyimides, polycarbonates, glass, alumina, Teflon, and conducting metals such as tungsten, molybdenum, and nickel (thereby making these materials suitable for construction of tubes).

However, it is apparent to one skilled in the art that a number of other liquid metals may be used without departing from the scope of the invention. For example, liquid metals having high thermal conductivity, high electrical conductivity and high volumetric heat capacity can be used. Some examples of liquid metals that can be used in an embodiment of the invention include mercury, gallim, sodium potassium eutectic alloy (78% sodium, 22%) potassium by mass), bismuth tin alloy (58% bismuth, 42% tin by mass), bismuth lead alloy (55% bismuth, 45% lead) etc. Bismuth based alloys are generally used at high temperatures (40 to 140° C.). Pure indium can be used at temperatures above 156° C. (i.e., the melting point of indium).

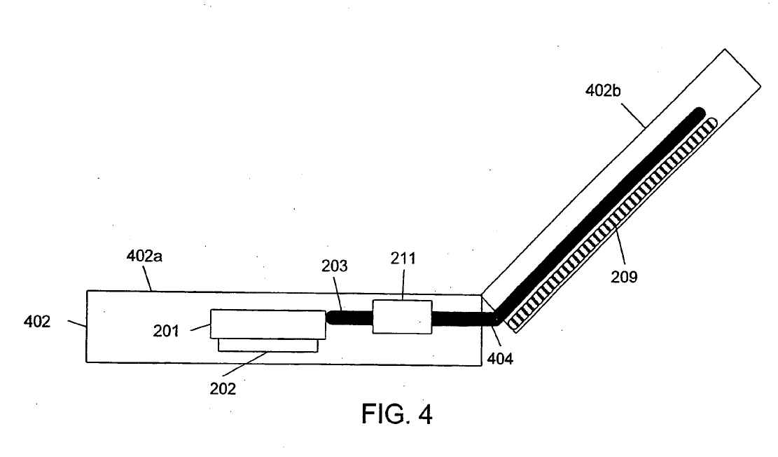

In accordance with another embodiment of the invention, the present invention provides a system for dissipating heat from a high power density device in a folding microelectronic device. This embodiment is shown in FIG. 4. Examples of folding microelectronic devices include notebook computers, a personal digital assistants (PDA's), tablet PC's or mobile phones. As shown in FIG. 4, a folding microelectronic device 402 includes a base member 402a and a folding member 402b. Base member 402a contains at least one high power density device 202. For example, in a laptop, base member 402a contains a processor, a graphics card and other such high power density devices.

In some embodiments, the system includes a solid-fluid heat exchanger 201, a conduit 203, at least one electromagnetic pump 211 and a heat sink 209. Solid-fluid heat exchanger 201 is filled with liquid metal that absorbs heat from high power density device 202. Conduit 203 passes through solid-fluid heat exchanger 201 and carries the heated liquid metal away. The liquid metal is pumped by at least one electromagnetic pump 211.

Conduit 203 includes a portion 404 that carries the heated liquid metal from base member 402a across the bend of folding microelectronic device 402 to folding member 402b. Further, portion 404 allows folding member 402b to bend with respect to base member 402a. Portion 404 is made of a flexible material that is inert to liquid metal. Exemplary materials include rubber, elastomer and Teflon™. Alternatively, entire conduit 203 (including portion 404) can be made of the flexible material.

Conduit 203 carries the liquid metal into folding member 402b of folding microelectronic device 402. Heat from the liquid metal in conduit 203 is transferred to heat sink 209, which is located in folding member 402b. Heat sink 209 then releases the heat to the atmosphere. After transferring heat to heat sink 209, the liquid metal returns to base member 402a through conduit 203 to complete the closed loop.

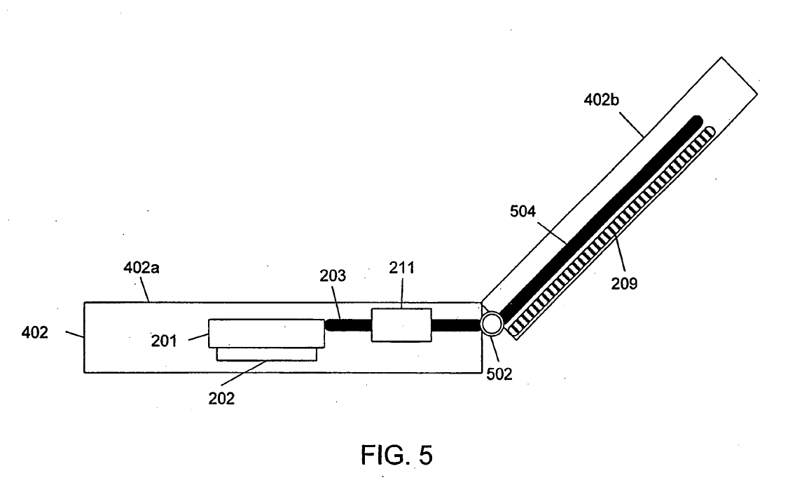

Another embodiment of the invention for dissipating heat from a high power density device in a folding microelectronic device is shown in FIG. 5. Such a system includes a hinge with an integrated conduit that allows heated liquid metal to flow from the base member to the folding member of a folding microelectronic device, while allowing the folding member to bend with respect to the base member.

FIG. 5 shows solid-fluid heat exchanger 201 filled with liquid metal. The liquid metal absorbs heat from high power density device 202. Conduit 203 carries the heated liquid metal away from solid-fluid heat exchanger 201. The liquid metal is pumped by at least one electromagnetic pump 211. Further, conduit 203 attaches to a hinge 502. Hinge 502 has an integrated conduit and allows the bending of folding member 402b with respect to base member 402a. Hinge 502 allows the liquid metal to flow through it and enter folding member 402b through a second conduit 504. Hinge 502 is made from materials that provide the mechanical rigidity required for bending of folding member 402b and are inert to the liquid metal. Examples of such materials include Teflon™, thermoplastics and metals such as copper, stainless steel and nickel. Alternatively, hinge 502 may be made of any other metal that is coated with a coating that is chemically resistant to the liquid metal.

Further, in folding member 402b, the liquid metal transfers heat to heat sink 209, which rejects heat to the atmosphere. Cold liquid metal returns to hinge 502 and flows through it to reach base member 402a through conduit 203. Further, the liquid metal flows to solid-fluid heat exchanger 201, hence completing a closed loop.

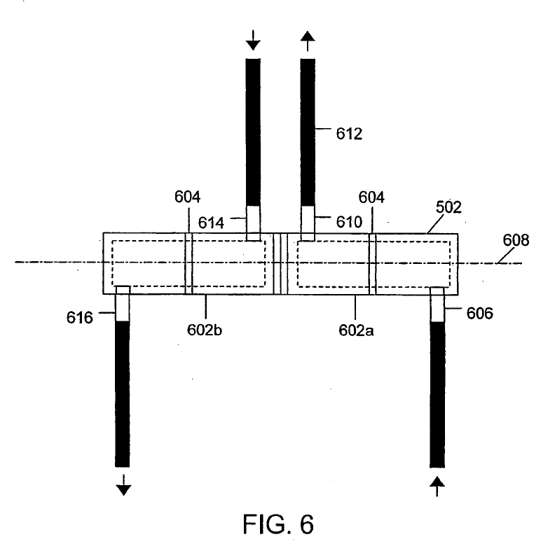

Referring to FIG. 6, hinge 502 includes portions 602a and 602b. Each of the portions 602a and 602b include a seal 604 that allows hinge 502 to rotate while preventing liquid metal from leaking. The seal may be formed by compressive contact between members 602a and 602b. It could also be formed using rotary joints with O-rings acting as seals. The O-rings may be made of materials such as Teflon™, Buna-n, and Viton™. Liquid metal enters hinge 502 through a port 606 on portion 602a.

Thereafter, it flows along axis of rotation 608 of hinge 502. Further, liquid metal leaves hinge 502 through a port 610 and enters conduit 612. After rejecting heat to heat sink 209, the liquid metal then returns to hinge 502 through a port 614 on portion 602b. The liquid metal leaves hinge 502 through port 616 and returns to conduit 203. Conduit 203 takes liquid metal back to solid-fluid heat exchanger 201. Portions 602a and 602b may also be implemented as separate hinges in microelectronic device 402.

The arrangement described with respect to FIG. 5 and FIG. 6 can also be used to distribute the hot liquid metal into a plurality of conduits in folding member 402b. The distribution of liquid metal into conduits helps in spreading the heat for better heat dissipation. The various conduits carry the liquid metal into a plurality of heat sinks in folding member 402b. In some realizations, portion 602a of hinge 502 have a plurality of outlet ports that distribute the liquid metal into the plurality of conduits in folding member 402b. After rejecting heat through heat sink 209, cooled liquid metal collects and enters hinge 502 through port 616 and returns to base member 402a. Furthermore, the embodiment described with respect to FIG. 5 and FIG. 6 does not require the conduit to be flexible. Hence, the system may be more reliable and the wear and tear on the conduit can be reduced.

The embodiments described with the help of FIG. 4 and FIG. 5 allow the dissipation of heat from the folding member of the microelectronic device. For example, heat is transferred from the base member of a laptop to the folding member of a laptop. Often, the folding member offers more space for incorporating a heat sink or more surface area from which to dissipate heat. Further, other components in the base member, such as memory and storage are protected from the heat.

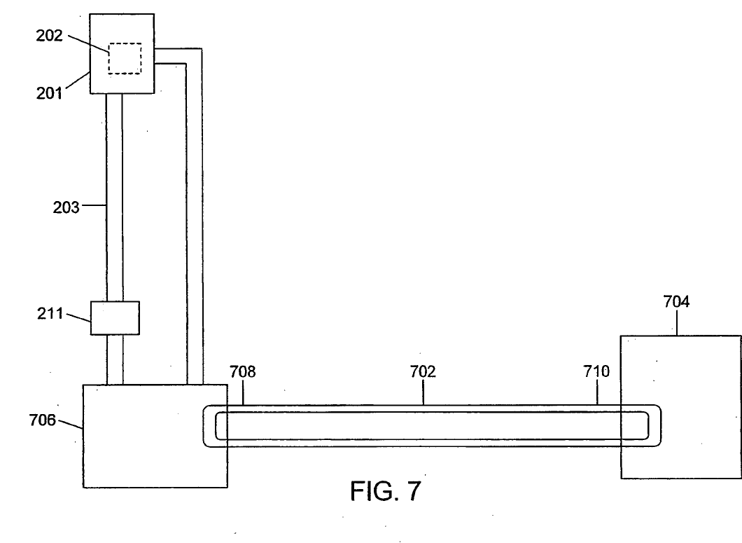

FIG. 7 shows yet another embodiment of the invention. FIG. 7 shows a system for dissipating heat from a microelectronic device. Such a system includes a solid-fluid heat exchanger 201, a conduit 203, at least one electromagnetic pump 211, a liquid-heat pipe heat exchanger 706, a heat pipe 702 and a heat sink 704. Liquid metal in solid-fluid heat exchanger absorbs heat from high power density device 202. The liquid metal flows through conduit 203. Electromagnetic pump 211 pumps the liquid metal in conduit 203.

In liquid-heat pipe heat exchanger 706, heat from the liquid metal is transferred to heat pipe 702. The cold liquid metal returns to solid-fluid heat exchanger 201 to complete the closed loop. Liquid at an end 708 of heat pipe 702 absorbs heat from the liquid metal, evaporates and moves to a cold end 710 of heat pipe 702. At cold end 710, the liquid condenses and dissipates heat to heat sink 704. The condensed liquid moves back to end 708 by gravity or capillary action of the inner limiting of heat pipe 702. Heat sink 704 then rejects the heat to the atmosphere.

The system as described above may be used with the flexible conduit as shown in FIG. 4 or the hinge with the integrated conduit as shown in FIG. 5. In such a system, the liquid metal system (typically including a solid-fluid heat exchanger, a conduit and a pump) carries heat from a high power density device across a bend in a microelectronic device. In the folding member of the microelectronic device, heat is transferred to at least one heat pipe with the help of a liquid-heat pipe heat exchanger. The heat pipe then carries the heat and dissipates the heat to the atmosphere through a heat sink.

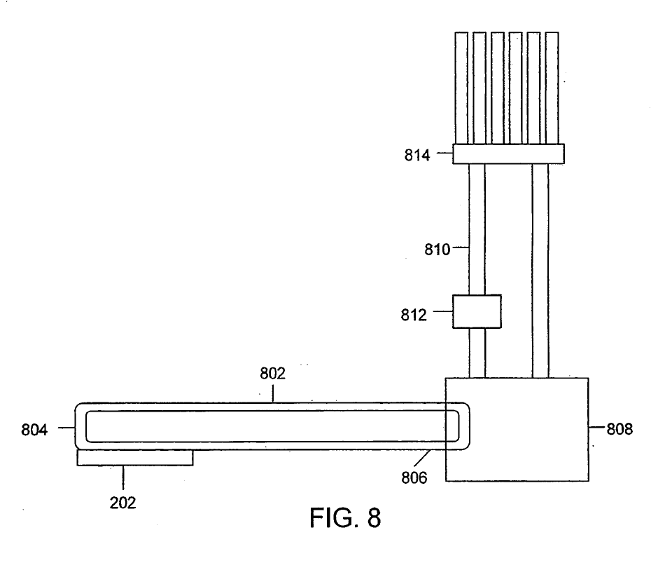

Yet another embodiment of the invention is shown in FIG. 8. The system shown in FIG. 8 includes a heat pipe 802, a liquid-heat pipe heat exchanger 808, a conduit 810, at least one electromagnetic pump 812 and a heat sink 814. Heat pipe 802 is placed adjacent to high power density device 202. A plate of any material having a high thermal conductivity may be used to ensure uniform heat transfer between high power density device 202 and heat pipe 802. In the preferred embodiment, a plate of copper is used. Heat pipe 802 may also be soldered onto high power density device. 202. Liquid at hot end 804 of heat pipe 802 absorbs heat from high power density device 202, evaporates and moves through heat pipe 802 to cold end 806. Cold end 806 is in direct contact with liquid metal in liquid-heat pipe heat exchanger 808. The evaporated vapor rejects heat to the liquid metal, condenses and moves back to hot end 804 by gravity or capillary action of the inner lining of heat pipe 802.

Heated liquid metal in liquid-heat pipe heat exchanger 808 is carried away by conduit 810. Electromagnetic pump 812 pumps the liquid metal through conduit 810. The liquid metal transfers heat to heat sink 814. Heat sink 814 rejects the heat to the atmosphere. Cooled liquid metal returns to liquid-heat pipe heat exchanger 808 through conduit 810, hence forming a closed loop.

The systems of liquid metal and heat pipes described above may be used for effective heat dissipation over large distances without requiring a large amount of liquid metal. This reduces the overall weight and the cost of the heat dissipation system.

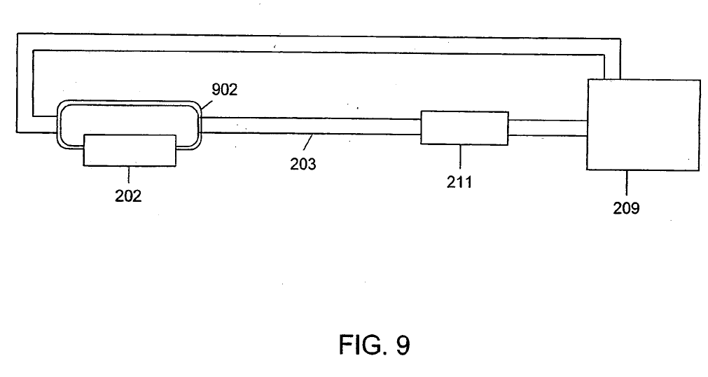

FIG. 9 shows one variation on previously described embodiments, in which liquid metal container 902 facilitates heat exchange between the liquid metal and a high power density device. Within sealed liquid metal container 902, liquid metal comes in direct contact with a high power density device, such as high power density device 202. This increases the efficiency of heat transfer to the liquid metal as there is little intermediate material between high power density device 202 and the liquid metal. The material of the surface of high power density device 202, which comes in direct contact with the liquid metal should be such that it is not corroded by the liquid metal. Exemplary materials for such a surface include copper plated with nickel, silicon dioxide and silicon coated with silicon nitride. Sealed liquid metal container 902 is sealed around the edges of high power density device 202. Sealed liquid metal container 902 could be constructed using a rigid and inert polymer (Teflon™, polyurethane, etc.), thermoplastics or metals such as copper, nickel.

Sealed liquid metal container 902 may be sealed in a number of ways depending on the nature of high power density device 202 to be cooled. A seal may be made using an interference fit between sealed liquid metal container 902 and high power density device 202. A seal may also be made using compressed O-rings or similar compression seals. The O-rings may be made of materials such as Teflon™, Buna-n, and Viton™. Addition of a bonding agent or a sealant, such as epoxy, may also be used to seal sealed liquid metal container 902. Sealed liquid metal container 902 may also be soldered or welded onto high power density device 202.

Furthermore, sealed liquid metal container 902 can be shaped according to the distribution of heat generated by high power density device 202, go enhance the heat transfer to the liquid metal. For example, if the heat generated at a specific part of high power density device 202 is more than the heat generated at other parts, scaled liquid. Metal container 902 can be shaped such that the volume of liquid metal that flows over this specific part is more than the volume of liquid metal that flows over other parts of high power density device 202. In this way, the total amount of liquid metal required for the system may be reduced. This would lead to a reduction in the weight and the cost of the system.

Liquid metal in liquid metal chamber is carried away by conduit 203. The liquid metal is pumped by at least one electromagnetic pump 211. Conduit 203 carries the liquid metal to heat sink 209. Heat sink 209 dissipates the heat from the liquid metal to the atmosphere. Cooled liquid metal is carried back to sealed liquid metal container 902 through conduit 203.

This embodiment increases the efficiency of heat transfer to the liquid metal. In some realizations, when a solid-fluid heat exchanger is used, an interface exists between a high power density device and the solid-fluid heat exchanger. Air gaps may exist on this interface due to the roughness of the surfaces of the solid-fluid heat exchanger and the high power density device. Air gaps reduce the heat transfer between the high power density device and the liquid metal. By allowing direct contact between the liquid metal and the high power density device, interface impediments to heat transfer can be reduced.

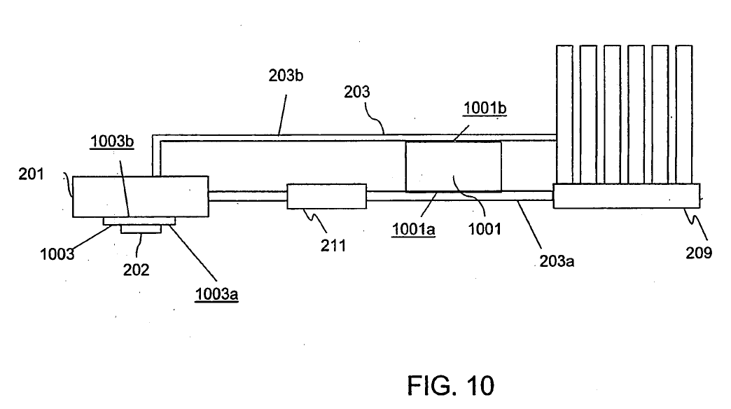

FIG. 10 shows additional features in accordance with some embodiments of the invention. In particular, FIG. 10 illustrates a thermoelectric generator 1001 and a thermoelectric cooler 1003. Thermoelectric generator 1001 is provided for powering electromagnetic pump 211 while thermoelectric cooler 1003 is provided for a first stage spot cooling of the high power density device 202.

A face 1001a of thermoelectric generator 1001 is placed in contact with section 203a of conduit 203. Section 203a carries hot liquid metal to heat sink 209 and has a high temperature. A Face 1001b of thermoelectric generator 1001 is placed in contact with section 203b of conduit 203 that carries liquid metal (that has been cooled after dissipating heat) away from the heat sink 209 to solid-fluid heat exchanger 201. Face 1001b is thus at a relatively low temperature. The temperature difference between the two faces of thermoelectric generator 1001 is utilized to produce potential deference for powering electromagnetic pump 211. Thus, in this case there is no need of external power source to run electromagnetic pump 211. The external power supply, if used, generates heat that has to be removed. This adds to the burden of heat removal from the system. By using potential difference generated by thermoelectric generator 213 to run electromagnetic pump 211, this added burden is done away with.

Thermoelectric generator 1001 includes a series of p type semiconductor members and n type semiconductor members sandwiched between thermally conducting, electrically-insulating substrates such as oxide-coated silicon wafers, aluminum nitride (AIN) and other thin ceramic wafers. Thermoelectric generator 1001 utilizes the “Seebeck effect” to convert the temperature difference between the hot section 203a and the cold section 203b of conduit 203 to electrical energy in the form of a potential difference. The voltage generated by thermoelectric generator 1001 depends on the temperature difference between the sections 203a and 203b. The performance (i.e. the ratio of electrical power to the heat flow into the hot end) of thermoelectric generator 1001 is governed by the Seebeck coefficient and thermal conductivity of p and n type semiconductor members used to form the device. Alloys of bismuth (Bi), tellurium (Te), antimony (Sb) and selenium (Se) are the most commonly used materials for manufacturing the semiconductor members of thermoelectric generator 1001 for devices operating near room temperature.

The use of thermoelectric generators provides sufficient power to drive the electromagnetic pumps. This may be illustrated using the following representative example:

The power requirement is dependent on the distance the fluid needs to move. Typically, this power requirement may range from few milli-watts (say for moving the fluid a distance of 10 cm in case of a laptop), to a watt (say for moving the fluid several meters in a server rack).

The coefficient of performance of a thermoelectric generator i.e. the ratio of electrical power to the heat flow into the hot end, is roughly:

η=ε(ΔT/Tₕ)

where ε; is the thermodynamic conversion efficiency, ΔT is the temperature differential between the hot and cold ends, and Tₕ is the temperature of the hot end. The value of ε; is 0.1 for conventional Bi/Sb/Te/Se alloys and Pb/Te/Se alloy materials. The typical temperature differential across the two ends of thermoelectric generator would be around 15-40K (i.e., Kelvin). Assuming ΔT=30 K and Tₕ=358 K (85° C.) the coefficient of performance η of the thermoelectric generator comes out to be 0.0084. If the high power density device dissipates 100W, the electrical power generated by the thermoelectric generator will be 0.84 W, which is sufficient for driving the electromagnetic pump. Of course, better thermoelectric generators can easily double the performance.

Thermoelectric cooler 1003 provides a first stage spot cooling of the high power density device 202. Thermoelectric cooler 1003 utilizes the “Peltier effect” to cool the high power density device 202. The construction of thermoelectric cooler 1003 is similar to thermoelectric generator 1001. A direct current supplied to the thermoelectric cooler 1003 produces a temperature difference between its two surfaces. Thus, surface of thermoelectric cooler 1003 in contact with high power density device 202 is at low temperature (with respect to high power density device 202) and surface of thermoelectric cooler in contact with solid-fluid heat exchanger 201 is at higher temperature (with respect to solid-fluid heat exchanger 201). The amount of cooling provided by thermoelectric cooler 1003 is a function of the current supplied to it. The use of thermoelectric cooler 1003 is desirable in cases where surface of high power density device 202 has uneven temperature distribution with some regions having temperature much greater than other regions. The first stage spot cooling provided by thermoelectric cooler 1003 helps to make temperature distribution uniform on the surface of high power density device 202.

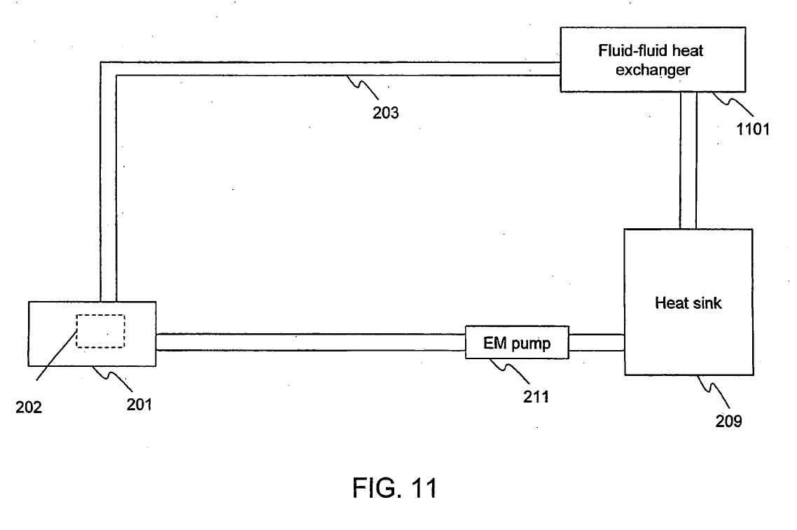

FIG. 11 shows yet another embodiment of the invention. In this embodiment a fluid-fluid heat exchanger 1101 is provided in addition to heat sink 209 for dissipating heat from the liquid metal. Fluid-fluid heat exchanger 1101 is provided for cases where additional cooling is required or the rate of cooling of liquid metal needs to be regulated. As shown in FIG. 11, liquid metal coming out through heat sink 209 is further cooled using heat exchanger 1101 before being circulated back to solid-fluid heat exchanger 201. Fluid-fluid heat exchanger 1101 makes use of a fluid to absorb the heat from liquid metal. This fluid enters fluid-fluid heat exchanger 1101 at one end absorbs heat from liquid metal and comes out through another end. Thus, heat is transferred from liquid metal to the fluid. The cooled liquid metal is then circulated back to solid-fluid heat exchanger 201 through section 203b of conduit 203. Electromagnetic pump 211 provides the power for circulating the liquid metal in form of a closed loop. In this manner, this embodiment provides for the transport and dissipation of heat at multiple positions away from high power density device 202 (shown using dashed lines).

Fluid-fluid heat exchangers make use of transfer of heat between two fluids over a common surface. Thus, use of liquid metal in the invention makes it possible to use a heat exchanger for dissipating heat. Fluid-fluid heat exchanger 1101 provides controlled cooling such that the rate of cooling may be regulated depending on requirements. The regulation of cooling rate may be achieved by varying the flow rate or temperature of the fluid in fluid-fluid heat exchanger 1101.

The fluids that are most commonly used in heat exchangers are water, air or freon. Fluid-fluid heat exchanger 1101 can be tubular shell and tube type of heat exchanger with counter or concurrent flow. Heat exchanger 1101 can also be a plate type heat exchanger. Fluid-fluid heat exchanger i 101 may be replaced by multiple heat exchangers connected in series or parallel. In fact, in place of the combination of heat exchanger 1101 and heat sink 209, heat exchanger 1101 alone can be used to dissipate heat. It will be apparent to one skilled in the art that any device that can dissipate/extract heat from liquid metal (e.g. thermoelectric cooler, vapor compression cooler) can replace heat exchanger 1101 without departing from the scope of the invention.

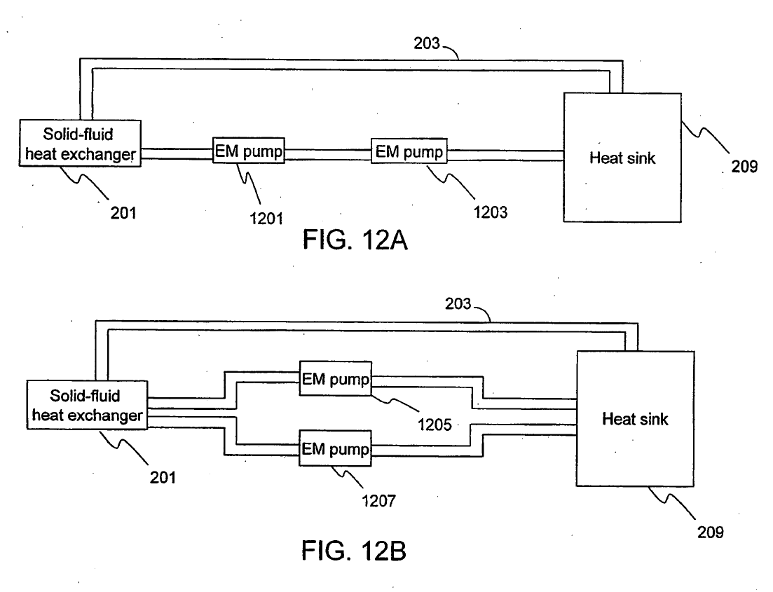

FIG. 12A shows two electromagnetic pumps 1201 and 1203 in series that pump liquid metal through conduit 203. Multiple electromagnetic pumps 1201 and 1203 are provided in series configuration where power supplied by one pump is not sufficient to circulate the liquid metal in the form of a closed loop. This may be the case when heat sink 209 is placed at a relatively large distance away from solid-fluid heat exchanger 201 (e.g. in case of a server rack). Two electromagnetic pumps 1201 and 1203 may also be useful where there is sudden loss in the pressure head. In case where the pipes take sharp turns (like in case of laptop joints) a significant drop in the pressure is observed. Due to reasons mentioned above more than two electromagnetic pumps may need to be provided in series.

FIG. 12B shows an alternate arrangement where two electromagnetic pumps 1205 and 1207 arranged in parallel. A parallel arrangement of electromagnetic pumps may be used in case there are some restrictions on the diameter of the conduit (say, due to form factor limitations). The parallel arrangement of pumps may also be used where there is a restriction on the size of the pump due to form factor limitations. Here many signal pumps in parallel can be used instead of one big sized pump.

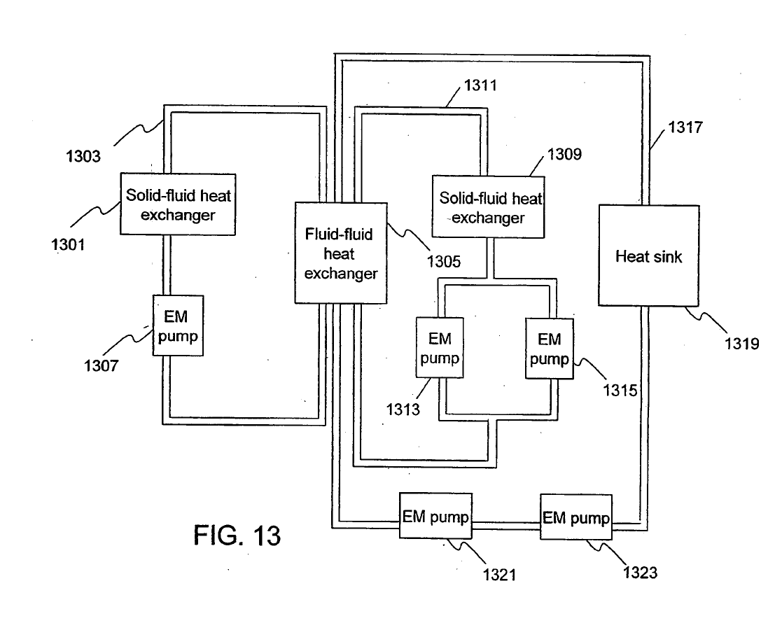

It will be apparent to one skilled in the art that the abovementioned embodiments may be combined in many ways to achieve flexibility in construction of heat dissipation systems. FIG. 13 shows one such design of a heat dissipating system. A solid-fluid heat exchanger 1301 placed adjacent to high power density device (not shown in FIG. 13) contains liquid metal. A conduit 1303 passes through solid-fluid heat exchanger 1301, carries away hot liquid metal and dissipates heat at a fluid-fluid heat exchanger 1305. EM pump 1307 powers the flow of liquid metal in closed conduit 1303. A solid-fluid heat exchanger 1309 (containing liquid metal) is placed adjacent to a second high power density device. A conduit 1311 carries hot liquid metal away from solid-fluid heat exchanger 1309 and dissipates heat at fluid-fluid heat exchanger 1305. Two electromagnetic pumps 1313 and 1315 power the flow of liquid metal in closed conduit 1311. Electromagnetic pumps 1313 and 1315 are connected in parallel. The heat transferred by conduits 1303 and 1311 to fluid-fluid heat exchanger 1305 is carried away by the liquid metal in closed conduit 1317. This heat is dissipated at heat sink 1319. A pair of electromagnetic pumps 1321 and 1323 power the flow of liquid metal in closed conduit 1317. Electromagnetic pumps 1321 and 1323 are connected in series.

This embodiment demonstrates the flexibility achieved by using liquid metal as a heat transfer medium. Closed conduits 1303 and 1309 (where liquid metal absorbs heat directly from high power density device) can be seen as primary closed conduits. Closed conduit 1317 can be seen as a secondary closed conduit (where liquid metal absorbs heat dissipated by other closed conduits). Thus, liquid metal in primary closed conduits 1303 and 1311 dissipates heat at common fluid-fluid heat exchanger 1305. This heat is carried away by liquid metal in secondary closed conduit 1317 and dissipated at heat sink 1319. It will be apparent that more complex networks of primary closed conduits and secondary closed conduits may be provided without departing from the scope of the invention. For example a network may have a plurality of primary and secondary closed conduits that dissipate heat at a common heat exchanger.

Besides physical flexibility, the use of liquid metal also provides design flexibility. As a result of the design flexibility, design of circuits based on electric considerations can be first worked out. Once the electric circuits have been designed, the liquid loops can be designed based on the form factor limitations (due to the circuit components). This approach enables the design of a circuit without taking thermal considerations in account in the first place.

The system may further include a heat spreader positioned adjacent to the high power density device. The heat spreader can include a plurality of cooling chambers containing liquid metal and a plurality of electromagnetic pumps arranged in a configuration so as to circulate the liquid metal in the cooling chambers.

From the above discussion it is evident that liquid metal heat transfer provides a highly flexible method of heat removal. The various embodiments provided by the invention may be used in computational devices such as laptops to dissipate heat generated by the central processing unit. The flow of liquid metal in conduits (made of polymers) provides a lot of flexibility to carry away the heat and dissipate it at a heat sink placed at bottom or screen of the laptop. The fluid conduit can be flexed, or bent, allowing the flow of liquid metal to be routed across hinges (in a laptop).

The networks of primary and secondary closed conduits provided by the invention can be used for cooling multiple processors in a server where several discrete high power density devices are located in close physical proximity. Primary closed conduits may be used to dissipate heat locally while secondary closed conduits can carry away this heat and dissipate it at distant less-populated areas on the board.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

1. A system for dissipating heat from a high power density device, the system comprising:
a pathway for transport of a liquid metal thermal transfer fluid, the pathway including a portion in close thermal communication with the high power density device; and
at least one electromagnetic pump for motivating flow of the liquid metal thermal transfer fluid through the liquid metal thermal transfer pathway away from and back to the high power density device,
wherein the high power density device is located in a folding device, and
wherein at least a portion of the liquid metal thermal transfer pathway traverses a bend in the folding device.

2. The system of claim 1,
wherein the bend traversing portion of the liquid metal thermal transfer pathway includes a flexible conduit.

3. The system of claim 1,
wherein the bend traversing portion of the liquid metal thermal transfer pathway includes a hinge that defines an integrated conduit therethrough.

4. The system of claim 1, further comprising:
a heat pipe; and
a heat exchanger coupled to transfer heat between the liquid metal thermal transfer fluid and the heat pipe.

5. The system of claim 1, further comprising:
the liquid metal thermal transfer fluid.

6. The system as recited in claim 1,
wherein the pathway portion in close thermal communication with the high power density device includes a solid-fluid heat exchanger.

7. The system as recited in claim 1,
wherein the pathway portion in close thermal communication with the high power density device includes a liquid metal chamber that allows direct thermal contact between the high power density device and the liquid metal.

8. The system of claim 1, further comprising:
a heat sink separated from the high power density device by a beat transfer path that includes the bend traversing portion of the liquid metal thermal transfer pathway.

9. A system for dissipating heat from a high power density device, the system comprising:
a pathway for transport of a liquid metal thermal transfer fluid, the pathway including a portion in close thermal communication with a heat pipe; and
at least one electromagnetic pump-for motivating flow of the liquid metal thermal transfer fluid through the pathway away from and back to the heat pipe,
wherein the pathway for transport of the liquid metal thermal transfer fluid and the heat pipe together define a heat transfer path away from the high power density device.

10. The system of claim 9,
wherein the high power density device is located in a folding device, and
wherein at least a portion of the liquid metal thermal transfer pathway traverses a bend in the folding device.

11. The system of claim 10,
wherein the bend traversing portion of the liquid metal thermal transfer pathway includes a flexible conduit.

12. The system of claim 10,
wherein the bend traversing portion of the liquid metal thermal transfer pathway includes a hinge that defines an integrated conduit therethrough.

13. The system of claim 9,
wherein the liquid metal thermal transfer pathway includes a portion in close thermal communication with the high power density device.

14. The system of claim 9,
wherein at least a portion of the liquid metal thermal transfer pathway is formed using a flexible conduit

15. The system of claim 9, further comprising:
the liquid metal thermal transfer fluid.

16. A method for dissipating heat from a high power density device, the method comprising: transferring heat from the high power density device to a liquid metal thermal transfer fluid;
motivating flow of the liquid metal thermal transfer fluid away from and back to the high power density device in a closed cycle fluid pathway; and
transferring heat from the liquid metal thermal transfer fluid flow to a heat pipe.

17. The method of claim 16, further comprising:
as part of the motivated flow of liquid metal thermal transfer fluid away from and back to the high power density device, transporting the liquid metal thermal transfer fluid through a flexible conduit portion of the closed cycle fluid pathway.

18. The method of claim i 6, further comprising:
as part of the motivated flow of liquid metal thermal transfer fluid away from and back to the high power density device, transporting the liquid metal thermal transfer fluid through a bend traversing portion of the closed cycle fluid pathway.

19. The system of claim 17, further comprising:
increasing and decreasing bend of the bend traversing portion of the closed cycle fluid pathway during the flow of liquid metal thermal transfer fluid.

20. The system of claim 18,
wherein the bend traversing portion of the closed cycle fluid pathway includes a flexible conduit portion.

21. The system of claim 18,
wherein the bend traversing portion of the closed cycle fluid pathway includes a hinge that defines an integrated conduit therethrough.

22. A method for dissipating heat from a high power density device, the method comprising:
transferring heat from the high power density device to a liquid metal thermal transfer fluid;
motivating flow of the liquid metal thermal transfer fluid away from and back to the high power density device in a closed cycle fluid pathway that traverses a bend in a folding device.

23. The method of claim 22, further comprising:
wherein the bend traversing portion of the closed cycle fluid pathway includes a flexible conduit portion.

24. The method of claim 22, further comprising:
wherein the bend traversing portion of the closed cycle fluid pathway includes a hinge that defines an integrated conduit therethrough.

25. The method of claim 22, further comprising:
increasing and decreasing the bend during the flow of liquid metal thermal transfer fluid.

26. The method of claim 22, further comprising:
transferring heat from the liquid metal thermal transfer fluid flow to a heat pipe.
